(19) United States
(12) Patent Application Publication
(10) Pub. No.: US 2026/0093279 A1
(43) Pub. Date: Apr. 2, 2026

(54) CYCLE-BY-CYCLE CURRENT ASSESSMENT USING DETECTION OF OPERATING CASES

(71) Applicant: QUALCOMM Incorporated, San Diego, CA (US)

(72) Inventors: Marko KOSKI, Chandler, AZ (US); Zdravko LUKIC, San Diego, CA (US); Edgar MARTI-ARBONA, Chandler, AZ (US); Ajay Kumar KOSARAJU, Singapore (SG); Pramod SENAPURA PRABHAKAR, Menifee, CA (US); Rashed HOQUE, Chandler, AZ (US); Gordon LEE, Gilbert, AZ (US); Orlando SANTIAGO, San Diego, CA (US); Troy Lynn STOCKSTAD, Chandler, AZ (US)

(21) Appl. No.: 18/900,403

(22) Filed: Sep. 27, 2024

(51) Int. Cl. G05F 1/565; H02M 1/00; H02M 1/32; H02M 3/158; H03L 7/081

(52) U.S. Cl. CPC G05F 1/565; H02M 1/0009; H02M 1/32; H02M 3/158; H03L 7/0814

(57) ABSTRACT

Certain aspects of the present disclosure are directed towards a current assessment circuit. The current assessment circuit generally includes: an operating case detector configured to detect a set of operating cases associated with a current of a voltage regulator to be measured, wherein the operating cases are associated with case-specific average currents for the voltage regulator, respectively; a weight circuit configured to generate an average current signal indicating the case-specific average currents for the voltage regulator; and an average detector configured to identify an average current across the set of operating cases based on the average current signal.

### TECHNICAL FIELD

Certain aspects of the present disclosure generally relate to electronic circuits and, more particularly, to current assessment circuitry.

### BACKGROUND

A voltage regulator may provide a constant direct current (DC) output voltage regardless of changes in load current or input voltage. Voltage regulators may be classified as linear regulators or switching regulators. While linear regulators tend to be relatively compact, many applications may benefit from the increased efficiency of a switching regulator. A linear regulator may be implemented by a low-dropout (LDO) regulator, for example. A switching regulator (also known as a “switching converter” or “switcher”) may be implemented, for example, by a switched-mode power supply (SMPS), such as a buck converter, a boost converter, a buck-boost converter, or a charge pump.

For example, a buck converter is a type of SMPS that may include: (1) a high-side switch coupled between a relatively higher voltage rail and a switching node, (2) a low-side switch coupled between the switching node and a relatively lower voltage rail, (3) and an inductor coupled between the switching node and a load. The high-side and low-side switches are typically implemented with transistors, although the low-side switch may alternatively be implemented with a diode.

Power management integrated circuits (power management ICs or PMICs) are used for managing the power scheme of a host system and may include and/or control one or more voltage regulators (e.g., buck converters and/or LDOs). A PMIC may be used in battery-operated devices, such as mobile phones, tablets, laptops, wearables, etc., to control the flow and direction of electrical power in the devices. The PMIC may perform a variety of functions for the device, such as DC-to-DC conversion (e.g., using a voltage regulator as described above), battery charging, power-source selection, voltage scaling, power sequencing, etc. In some cases, an inductor current or output current of a voltage regulator may be detected for various applications such as fault protection, dynamic control algorithms, and energy monitoring.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards a current assessment circuit. The current assessment circuit generally includes: a comparison circuit configured to compare a current associated with a voltage regulator with a current track threshold to yield a state flag signal; a duty cycle detection circuit configured to detect a duty cycle of the state flag signal; and a controller configured to adjust the current track threshold to asses a first average of the current based on the duty cycle of the state flag signal, wherein the current track threshold is adjusted by an amount based on the duty cycle.

Certain aspects of the present disclosure are directed towards a current assessment circuit. The current assessment circuit generally includes: an operating case detector configured to detect a set of operating cases associated with a current of a voltage regulator to be measured, wherein the operating cases are associated with case-specific average currents for the voltage regulator, respectively; a weight circuit configured to generate an average current signal indicating the case-specific average currents for the voltage regulator; and an average detector configured to identify an average current across the set of operating cases based on the average current signal.

Certain aspects of the present disclosure are directed towards a method for current assessment. The method generally includes: comparing a current associated with a voltage regulator with a current track threshold to yield a state flag signal; detecting a duty cycle of the state flag signal; and adjusting the current track threshold to assess a first average of the current based on the duty cycle of the state flag signal, wherein the current track threshold is adjusted by an amount based on the duty cycle.

Certain aspects of the present disclosure are directed towards a method for current assessment. The method generally includes: detecting a set of operating cases associated with a current of a voltage regulator to be assessed, wherein the operating cases are associated with case-specific average currents for the voltage regulator, respectively; generating an average current signal indicating the case-specific average currents for the voltage regulator; and identifying an average current across the set of operating cases based on the average current signal.

Certain aspects of the present disclosure are directed towards an apparatus for voltage regulation. The apparatus generally includes a voltage regulator and a current assessment circuit, comprising: a comparison circuit configured to compare a current associated with the voltage regulator with a current track threshold to yield a state flag signal; a duty cycle detection circuit configured to detect a duty cycle of the state flag signal; and a controller configured to adjust the current track threshold to assess a first average of the current based on the duty cycle of the state flag signal, wherein the current track threshold is adjusted by an amount based on the duty cycle.

Certain aspects of the present disclosure are directed towards an apparatus for voltage regulation. The apparatus generally includes a voltage regulator and a current assessment circuit comprising: an operating case detector configured to detect a set of operating cases associated with a current of the voltage regulator to be assessed, wherein the operating cases are associated with case-specific average currents for the voltage regulator, respectively; a weight circuit configured to generate an average current signal indicating the case-specific average currents for the voltage regulator; and an average detector configured to identify an average current across the set of operating cases based on the average current signal.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates an example device in which aspects of the present disclosure may be implemented.

FIG. 2 illustrates a circuit diagram of an example buck converter and timing diagrams for the buck converter in different operating modes.

FIG. 3 illustrates an example inductor current of a buck converter compared to different current tracking thresholds.

FIG. 4 illustrates multiple bins used for current assessment, in accordance with certain aspects of the present disclosure.

FIG. 5 illustrates an example current assessment circuit using at least one analog time-to-digital converter (TDC), in accordance with certain aspects of the present disclosure.

FIG. 6A illustrates an example current assessment circuit using a digital TDC, in accordance with certain aspects of the present disclosure.

FIG. 6B is a timing diagram illustrating signals of the current assessment circuit of FIG. 6A, in accordance with certain aspects of the present disclosure.

FIG. 7 is a graph illustrating an inductor current of a converter during different operating cases, in accordance with certain aspects of the present disclosure.

FIG. 8 illustrates example assessment circuitry for measuring current during continuous conduction mode (CCM) and pulse-skip mode (PSM) of a voltage regulator, in accordance with certain aspects of the present disclosure.

FIGS. 9 and 10 are flow diagrams illustrating example operations for current assessment, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards a current assessment circuit that may be used to measure a current associated with a voltage regulator, such as a switched-mode power supply (SMPS). For example, the current may be an inductor current or an output current of the SMPS, although any suitable current may be assessed (e.g., measured) using the techniques described herein. In some cases, the current of the voltage regulator may be represented by a triangle wave. Thus, a state flag signal including a pulse may be generated by comparing the current of the voltage regulator (e.g., triangle wave) with a current track threshold. The duty cycle of the state flag signal may correspond to the average of the voltage regulator current. The duty cycle of the state flag may be detected, and the current track threshold may be adjusted based on the duty cycle until the duty cycle is 50% (e.g., or at least within a certain threshold of 50%), such that the current track threshold represents an average of the voltage regulator current. In some cases, non-linear feedback may be used to adjust the current track threshold, reducing the latency associated with the current assessment. For example, each of multiple duty cycle bins may correspond to a duty cycle difference between the duty cycle of the state flag signal and a duty cycle of 50%. The current track threshold may be adjusted using the multiple duty cycle bins. The amount by which the current track threshold is adjusted may be based on the duty cycle difference (e.g., or the associated bin) between the duty cycle of the state flag signal and a duty cycle of 50%, as described in more detail herein. The greater the duty cycle difference, the more aggressively the current track threshold may be adjusted to identify the average voltage regulator current more quickly.

In some cases, the current assessment may be performed by adjusting the current track threshold when the voltage regulator is operating in continuous conduction mode (CCM). Another current assessment technique may be used when operating in pulse-skip mode (PSM). For example, different operating cases of the voltage regulator may be identified where an average current is predetermined to be associated with each operating case. Thus, based on the predetermined average currents associated with the identified operating cases, the average current of the voltage regulator may be determined, as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatuses, such as in the power supply, battery charging circuit, or power management circuit of a communication system, a video codec, audio equipment such as music players and microphones, a television, camera equipment, and test equipment such as an oscilloscope.

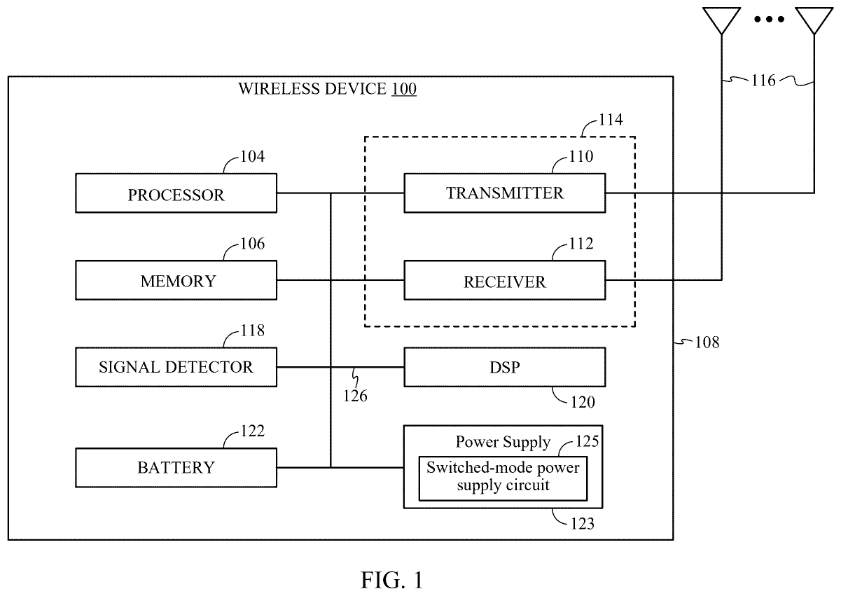

FIG. 1 illustrates an example device 100 in which aspects of the present disclosure may be implemented. The device 100 may be a battery-operated device such as a cellular phone, a personal digital assistant (PDA), a handheld device, a wireless device, a laptop computer, a tablet, a smartphone, an Internet of things (IoT) device, a wearable device, a virtual reality (VR) or augmented reality (AR) device, etc.

The device 100 may include a processor 104 that controls operation of the device 100. The processor 104 may also be referred to as a central processing unit (CPU). Memory 106 provides instructions and data to the processor 104. The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when the device is disconnected from an external power source). The device 100 may also include a power supply system 123 for managing the power from the battery (or from one or more power ports for receiving external power) to the various components of the device 100. At least a portion of the power supply system 123 may be implemented in one or more power management integrated circuits (power management ICs or PMICs) The power supply system 123 may perform a variety of functions for the device 100 such as DC-to-DC conversion, battery charging, power-source selection, voltage scaling, power sequencing, etc. For example, the power supply system 123 may include one or more power supply circuits, which may include a switched-mode power supply circuit 125. The switched-mode power supply circuit 125 may be implemented by any of various suitable switched-mode power supply circuit topologies, such as a three-level buck converter, a divide-by-two (Div2) charge pump, or an adaptive combination power supply circuit, which can switch between operating in a three-level buck converter mode and a two-level buck converter mode. In some aspects, the PMIC may include circuitry for current detection for the switched-mode power supply circuit 125, as described in more detail herein.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example Power Supply Scheme

Certain aspects of the present disclosure are directed towards techniques for current detection. The current detection may be performed for any suitable circuit, such as a voltage regulator, which may be a boost converter, buck converter, or buck-boost converter. For example, certain aspects provide current, power, or energy-sensing circuits that may be used in power management circuits (e.g., direct-current (DC)-DC converters). The current, power, or energy sensing circuitry described herein may be used for any suitable application, such as fault protection schemes, dynamic control algorithms using a current as a control input variable, or energy system monitoring. Certain aspects may be used for any suitable electronic device or application such as automotive electronics, avionics, medical devices, military weapons, and any other complex electronic hardware where current information is important for protection and/or system regulation.

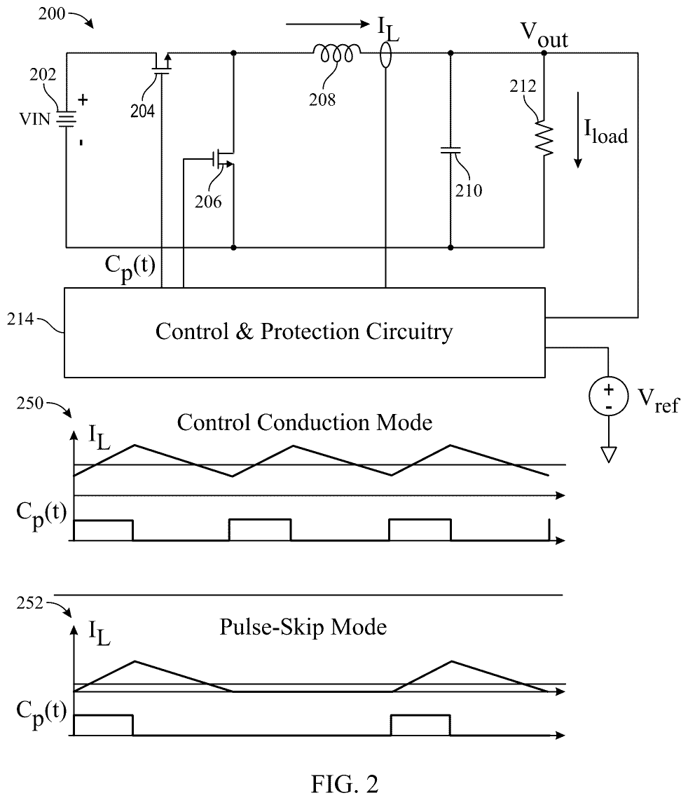

FIG. 2 illustrates a circuit diagram of an example buck converter 200. As shown, the buck converter 200 may receive an input voltage VIN (e.g., from a battery 202, a wall adapter, or another power supply circuit) and may generate a regulated output voltage (Vₒᵤₜ). The Vₒᵤₜ node may be coupled to a load represented by resistive element 212. The converter 200 may include switches 204, 206 (e.g., implemented via transistors) that may control the current flow across an inductive element 208 to generate the regulated output voltage. For example, a control signal Cₚ(t) may be used to control the switch 204, and a signal complementary to Cₚ(t) may be used to control the switch 206. As shown in diagram 250, when Cₚ(t) is logic high, the switch 204 may be closed (and the switch 206 may be open), and the inductor current I_{L} may increase, charging an output capacitive element 210. When the switch 204 is open and switch 206 is closed, I_{L} may decrease, as shown. Vₒᵤₜ may be fed back to a control and protection circuit 214 and compared to a reference voltage V_{ref}. Based on the comparison, the switches 204, 206 may be controlled by the control and protection circuit 214 to set Vₒᵤₜ equal to V_{ref} for voltage regulation. In some cases, the converter 200 may operate in continuous conduction mode (CCM) as shown in diagram 250, during which I_{L} may not reach zero. In some cases, the converter 200 may also operate in a pulse-skip mode (PSM) as shown in diagram 252. During the PSM, one or more pulses of the control signal Cₚ(t) may be skipped as shown, increasing the converter's efficiency. Thus, during PSM, I_{L} may reach zero.

Power converters may be used to efficiently deliver regulated power to a load device (e.g., such as a central processing unit (CPU) or graphical processing unit (GPU)). Both output voltage and current flow assessments are important for power flow control and power converter protection. Multiple converters may be placed in parallel to deliver more current to a load. Converters typically operate in CCM. Pulse-skip control techniques may be used to reduce converter switching frequency to improve efficiency at light loads. Low-latency current information is important for protection and control algorithms in all modes. A digitized form of a current assessment may be used to provide a cost-effective current assessment implementation.

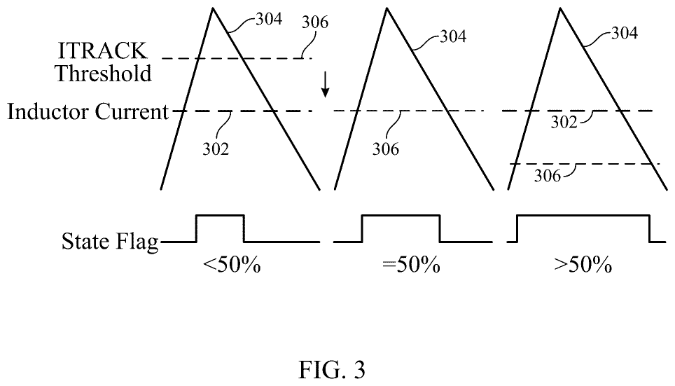

FIG. 3 illustrates inductor current 304. As shown, the inductor current 304 may be in the form of a triangle wave with a portion of time when the inductor current increases and a portion of time when the inductor current decreases. A current track (ITRACK) threshold 306 may be compared to the inductor current 304 to generate a state flag signal (e.g., a pulse signal) that may transition from logic low to logic high when the inductor current 304 increases above the ITRACK threshold 306 and may transition from logic high to logic low when the inductor current 304 decreases below the ITRACK threshold 306. When the state flag signal has a 50% duty cycle, the inductor current 304 may be about equal parts above the ITRACK threshold and equal parts below the ITRACK threshold. Thus, ITRACK threshold may represent the average 302 of the inductor current 304. When the state flag signal has a duty cycle of less than 50%, the inductor current average 302 may be less than the ITRACK threshold, and when the state flag signal has a duty cycle of greater than 50%, the inductor current average 302 may be more than the ITRACK threshold.

In some aspects of the present disclosure, the inductor current 304 may be compared to an ITRACK threshold to generate the state flag signal. The duty cycle of the resultant state flag signal may be determined. Based on the duty cycle of the state flag signal, the ITRACK threshold may be adjusted until the duty cycle becomes 50% (e.g., or within some threshold difference of 50%) so that the ITRACK threshold represents the average of the inductor current 304. In some aspects, multiple duty cycle bins may be used to decrease the latency associated with the current assessment.

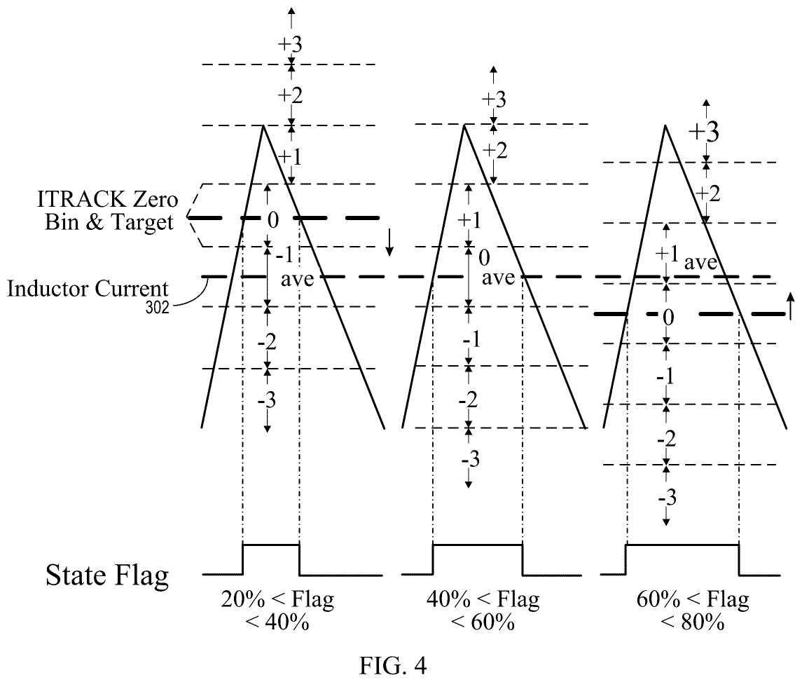

FIG. 4 illustrates multiple bins used for current tracking, in accordance with certain aspects of the present disclosure. For example, there may be seven bins labeled “−3” to “+3”, although any suitable number of bins may be used. The ITRACK threshold may represent bin 0, as shown. As shown, when the inductor current average 302 is in bin −1, the state flag signal may have a duty cycle between 20% and 40%. When the inductor current average 302 is in bin 0, the state flag signal may have a duty cycle between 40% and 60%. When the inductor current average 302 is in bin +1, the state flag signal may have a duty cycle between 60% and 80%, as shown.

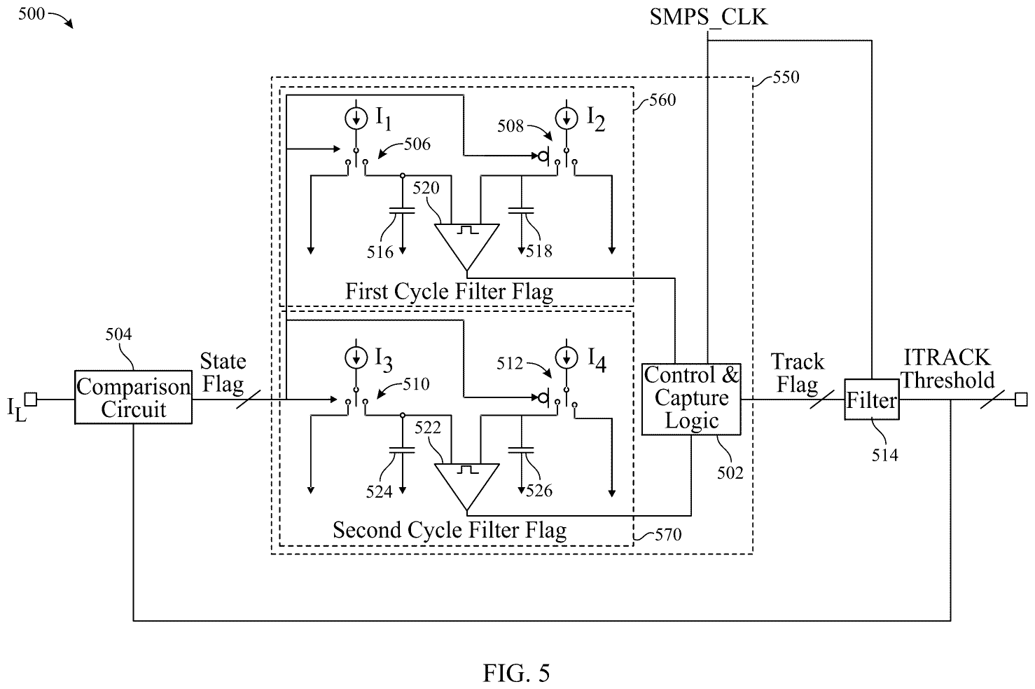

FIG. 5 illustrates an example current assessment circuit 500 using at least one analog time-to-digital converter (TDC), in accordance with certain aspects of the present disclosure. As shown, the circuit 500 may include a comparison circuit 504 that may receive the inductor current I_{L} (or a signal representative thereof, such as a voltage signal). The inductor current I_{L} ((or a signal representative thereof) may be compared to the ITRACK threshold (or a signal representative thereof) to generate the state flag, as described herein. The state flag may be provided to a duty cycle detection circuit 550 to detect a duty cycle of the state flag pulse. The circuit 550 may include TDCs 560, 570. For example, the circuit 550 may detect whether the duty cycle is in one of multiple duty cycle bins, such as between 20% to 40%, between 40% and 60%, and between 60% and 80%, using the TDCs 560, 570.

As shown, the TDC 560 may include current sources labeled “I₁” and “I₂.” Via switch 506, the current from the current source I₁ may be directed to a reference potential node (e.g., electric ground) if the state flag is logic low or directed to a capacitive element 516 to charge the capacitive element 516 if the state flag is logic high. On the other hand, via switch 508, the current from the current source I₂ may be directed to the reference potential node (e.g., electric ground) if the state flag is logic high or directed to a capacitive element 518 to charge the capacitive element 518 if the state flag is logic low. The voltages across capacitive elements 516, 518 may be compared via a comparator 520 to generate a first cycle filter flag signal that is provided to control and capture logic 502. The difference between the voltages of the capacitive elements 516, 518 may represent the duty cycle of the state flag signal.

Similarly, the TDC 570 may include current sources labeled “I₃” and “I₄.” Via switch 510, the current from the current source I₃ may be directed to the reference potential node (e.g., electric ground) if the state flag is logic low or directed to a capacitive element 524 to charge the capacitive element 524 if the state flag is logic high. On the other hand, via switch 512, the current from the current source 14 may be directed to the reference potential node (e.g., electric ground) if the state flag is logic high or directed to a capacitive element 526 to charge the capacitive element 526 if the state flag is logic low. The voltages across capacitive elements 524, 526 may be compared via a comparator 522 to generate a second cycle filter flag signal that is provided to control and capture logic 502.

The thresholds associated with the comparators 520, 522 may be different and set so that the first cycle filter flag signal at the output of the comparator 520 transitions from logic low to logic high when the duty cycle of the state flag signal increases above a first duty cycle (e.g., 40%) and so that the second cycle filter flag signal at the output of the comparator 522 transitions from logic low to logic high when the duty cycle of the state flag signal increases above a second duty cycle (e.g., 60%) greater than the first duty cycle. Thus, after each cycle and based on the first and second cycle filter flag signals, the logic 502 may output a track flag signal indicating whether the duty cycle of the state flag signal is greater than the first duty cycle, between the first duty cycle and the second duty cycle, or greater than the second duty cycle, effectively implementing three duty cycle bins. While the circuit 500 includes two TDCs to implement three bins, any suitable number of bins may be used with additional TDCs.

Based on the track flag signal, a filter 514 may generate the ITRACK threshold that is fed back to the comparison circuit 504. The filter 514 may adjust the ITRACK threshold until the track flag signal indicates that the duty cycle of the state flag signal is about 50% (e.g., is within the first duty cycle and the second duty cycle). In some aspects, the logic 502 and filter 514 may receive a clock signal (e.g., a clock signal for an SMPS, such as the converter 200, labeled “SMPS_CLK”) for generating the track flag signal and ITRACK threshold for each configured cycle, respectively.

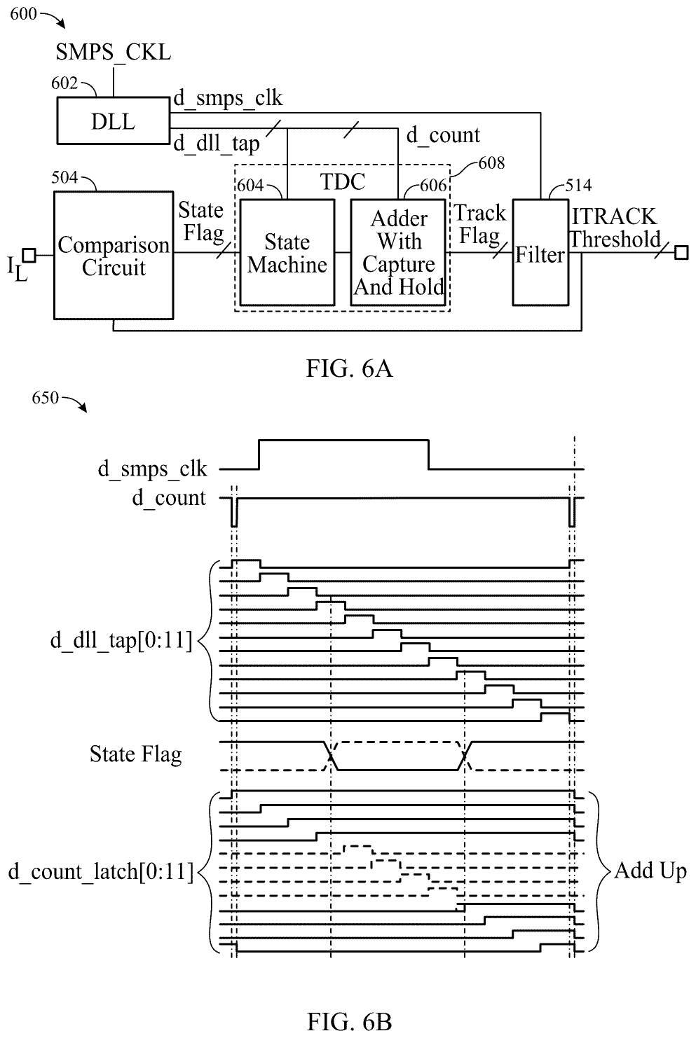

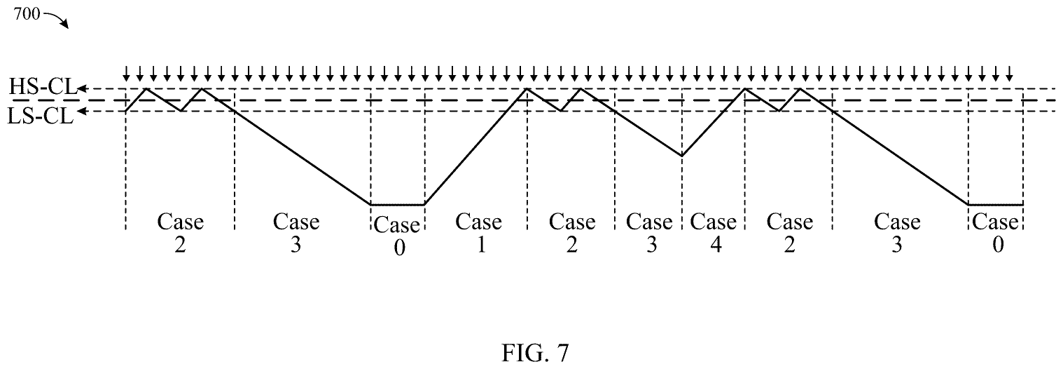

FIG. 6A illustrates an example current assessment circuit 600 using a digital time-to-digital converter (TDC), in accordance with certain aspects of the present disclosure. FIG. 6B is a timing diagram 650 illustrating signals of the circuit 600, in accordance with certain aspects of the present disclosure. As shown, the circuit 600 may include a delay-locked loop (DLL) 602 that may receive a clock signal (e.g., an SMPS clock labeled “SMPS_CLK”). Based on the clock signal, the DLL 602 may generate digital DLL tap (d_dll_tap) signals. The d_dll_tap signals include a set of sequential pulses as shown in diagram 650. As illustrated, the sequential pulses in the set are non-overlapping. For example, there may be twelve d_dll_tap signals (d_dll_tap[0:11]), although any suitable number of d_dll_tap signals may be used. The DLL 602 may also generate a digital count (d_count) signal. The d_count signal may indicate the beginning and end of a configured cycle for the current assessment. For example, a first inverse pulse (e.g., a pulse starting from logic high, transitioning to logic low, then transitioning back to logic high) may indicate the beginning of the cycle, and a second inverse pulse may indicate the end of the cycle, as shown.

The d_count signal may be provided to an adder with capture and hold circuit 606, which may be part of a TDC 608. The state flag signal from the comparison circuit 504 and the d_dll_tap signals may be provided to a state machine 604 of the TDC 608. The state machine 604 may generate digital count latch (d_count_latch[0:11]) signals as shown in diagram 650. Each of the d_count_latch[0:11] signals corresponds to a respective one of the d_dll_tap signals. For example, d_count_latch[0] may transition from logic low to logic high based on d_dll_tap[0] transitioning from logic low to logic high. When d_dll_tap[0] transitions to logic low, d_count_latch[0] also transitions to logic low if the state flag signal is logic low. Otherwise, d_count_latch[0] remains logic high. The d_count_latch[0:11] signals may be processed in a similar manner. At the end of the cycle as indicated by the d_count signal, the circuit 606 adds up the d_count_latch[0:11] signals that are logic high to generate a track flag signal indicating the duty cycle of the state flag signal. The track flag signal may be then provided to the filter 514 to generate the ITRACK threshold that is fed back to the comparison circuit 504, as described.

With the digital implementation described with respect to FIGS. 6A and 6B, multiple duty cycle bins may be implemented, each bin corresponding to a duty cycle difference between the duty cycle of the state flag signal and a duty cycle of 50%. That is, as described, the amount by which the ITRACK threshold is adjusted may be based on the duty cycle difference (e.g., or the associated bin) between the duty cycle of the state flag signal and a duty cycle of 50%. The greater the duty cycle difference, the more aggressively the ITRACK threshold may be adjusted to identify the average voltage regulator current more quickly.

As described, a converter, such as the converter 200 of FIG. 2, may operate in either CCM or PSM. In some aspects, the techniques described herein for current assessment with respect to FIGS. 3-5, 6A, and 6B may be performed when the converter is operating in CCM. Some aspects of the present disclosure are directed toward current assessments that may be performed when the converter is in PSM.

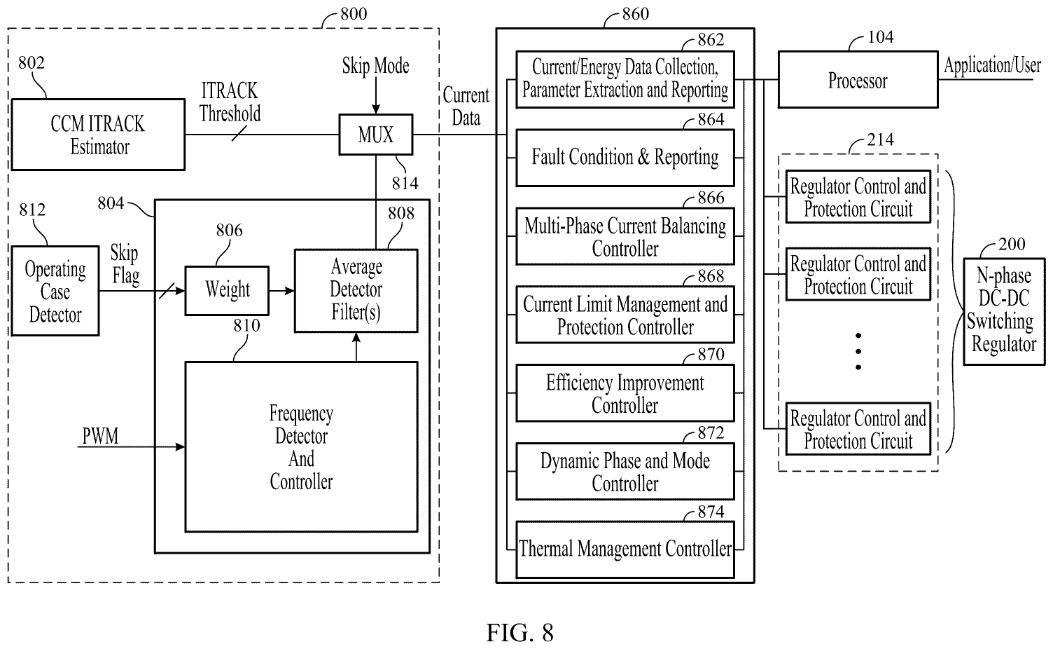

FIG. 7 is a graph 700 illustrating an inductor current of a converter during different operating cases, in accordance with certain aspects of the present disclosure. For example, during case 0, the inductor current may be at zero amps due to the converter operating in PSM. During case 1, the inductor current may increase from zero amps to a high-side current limit (HS-CL) for the converter. During case 2, the inductor current may transition between the HS-CL and low-side current limit (LS-CL), as shown. During case 3, the inductor current may drop below the HS-CL, either dropping to zero amps or increasing again before reaching zero amps. During case 4, the inductor current may increase to the HS-CL. Each of the operating cases may be identified during the converter operation.

An average of the inductor current for each case may predetermined. For example, during case 0, the average inductor current may be zero amps. During case 1, the average inductor current may be equal to:

$$\frac{HS\_CL}{2}$$

During case 2, the average inductor current may be equal to:

$$\frac{HS\_CL + LS\_CL}{2}$$

During case 3, the average inductor current may be equal to:

$$\frac{LS\_CL}{2}$$

During case 4, the average inductor current may be equal to:

$$\frac{( HS\_CL + 0.5 \times LS\_CL )}{2}$$

The different averages across the different operating cases may be used to detect the average inductor current during PSM. The average currents for cases 3 and 4 may be statistical approximations to reduce measurement error.

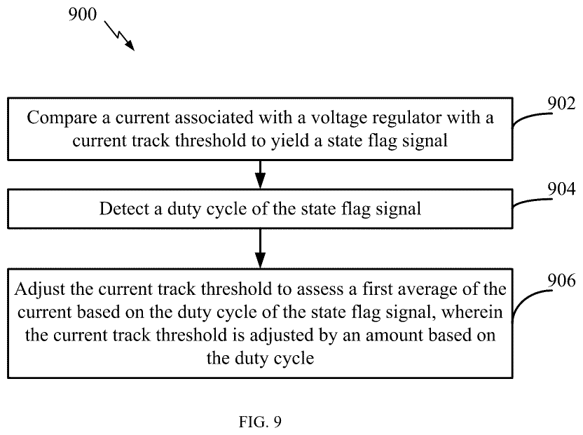

FIG. 8 illustrates an example current assessment circuit 800 for measuring current during CCM and PSM, in accordance with certain aspects of the present disclosure. As shown, the circuit 800 may include a CCM ITRACK estimation circuit 802 (e.g., labeled “CCM ITRACK Estimator,” which may correspond to the circuit 500 of FIG. 5 or the circuit 600 of FIG. 6A. The circuit 802 may generate the ITRACK threshold representing the inductor current during CCM.

The circuit 800 may also include a current assessment circuit 804 for measuring the inductor current during PSM. The circuit 804 may include a weight circuit 806 that may receive a skip flag signal generated via an operating case detector 812. The operating case detector 812 may identify each of the operating cases described with respect to FIG. 7 and indicate each operating case to the weight circuit 806 via the skip flag signal. The weight circuit 806 may generate a weight signal representing the average inductor current during each of the operating cases. The weight signal may be provided to an average detector 808, including one or more filters (e.g., low-pass filters). The average detector may filter the weight signal to generate a PSM current assessment signal representing the average inductor current across multiple operating cases based on the weight signal and the duration of each operating case.

In some cases, the bandwidth (e.g., cut-off frequency) of the one or more filters of the average detector 808 may be adjusted based on the operating frequency (e.g., the switching frequency) of the converter. For example, a pulse-width modulated (PWM) signal used to control the switches of the converter may be provided to a frequency detector and controller 810. Based on the frequency of the PWM signal, the controller 810 may adjust the bandwidth of the one or more filters.

In some aspects, the PSM assessment signal and the ITRACK threshold (e.g., the circuit 802) may be provided to a multiplexer 814. Depending on the operating mode of the converter (e.g., CCM or PSM), the multiplexer 814 may output, as current data (e.g., average current data), one of the ITRACK threshold or the PSM assessment signal. As shown, the current data (e.g., ITRACK threshold) output by the multiplexer 814 may be provided to control circuitry 860 for performing various improvement tasks. For example, the control circuitry 860 may include a current/energy data collection, parameter extraction and reporting controller 862, a fault condition and reporting controller 864, a multi-phase current balancing controller 866, current limit management and protection controller 868, efficiency improvement controller 870, dynamic phase and mode controller 872, and thermal management controller 874. The control circuitry 860 may be coupled to a processor 104 that may be used to report current data to an application or user. The control circuitry 860 may also be coupled to regulator control and protection circuitry 214 including one or more control and protection circuits for each phase of an N-phase DC-DC switching regulator (e.g., corresponding converter 200, where N is a positive integer).

Certain aspects have provided one or more current assessment circuits arranged and used for system level diagnostics. For example current data generated by the assessment circuits may be used for telemetry measurements for readouts and logging, fault condition reporting, or hardware configuration adjustments. The one or more current assessment circuits may be implemented in a control loop for device improvements. For example, the current data may be used for improve efficiency which could be implemented by way of managing operating modes and/or operational states of any of subsystem components when assembled from a plurality of power delivery components. For example, one or more phases of a converter may be activated to operate at improved efficiency based on monitoring of total power demand using the current data from the one or more current assessment circuits.

In some aspects, the current data may be used for thermal management. For example, the current data may be used to balance or distribute thermal conditions based on mapping of power delivery profiles of subsystem components and channeling or otherwise adjusting where power is dissipated and delivered. As an example, a product's temperature at specified sense point(s) may be fed into a thermal management algorithm which can make adjustments to avoid excessive thermal excursions at sense/control points of importance (e.g., product skin temperature or in proximity to thermally sensitive circuitry). In some aspects, current data may be provided as input to a control loop that may be used to manage spectral energy emissions to avoid objectionable audible noise.

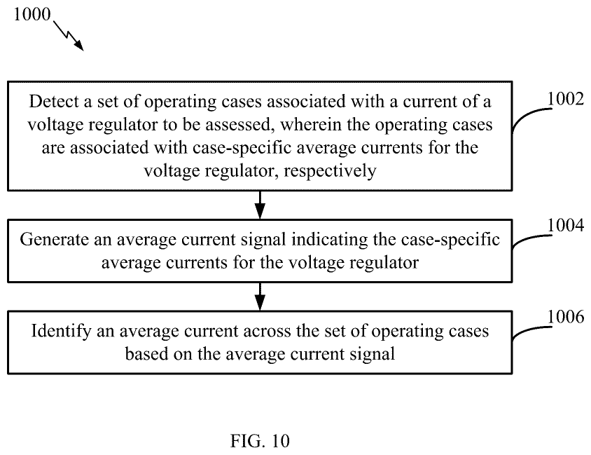

FIG. 9 is a flow diagram illustrating example operations 900 for current assessment, in accordance with certain aspects of the present disclosure. The operations 900 may be performed, for example, by a current assessment circuit, such as the current assessment circuit 600 or current assessment circuit 800.

At block 902, the current assessment circuit may compare a current associated with a voltage regulator (e.g., SMPS such as converter 200) with a current track threshold (e.g., ITRACK threshold) to yield a state flag signal. At block 904, the current assessment circuit may detect a duty cycle of the state flag signal. At block 906, the current assessment circuit may adjust the current track threshold to assess a first average of the current based on the duty cycle of the state flag signal. The current track threshold may be adjusted by an amount based on the duty cycle. In some cases, the current track threshold may be adjusted non-linearly based on the duty cycle.

In some aspects, the current assessment circuit may generate a set of sequential pulses (e.g., d_dll_tap signals of FIG. 6B), generate a set of latch signals (e.g., d_count_latch signals of FIG. 6B) based on the state flag signal, and count a quantity of the latch signals that have a first logic value in an assessment cycle. In some aspects, each of the set of latch signals transitions from a second logic value low to the first logic value high based on the state flag signal. The duty cycle detection circuit may be configured to generate each of the set of latch signals based on a respective one of the set of sequential pulses. In some aspects, the pulse generator comprises a DLL (e.g., DLL 602).

In some aspects, the current track threshold is adjusted until the duty cycle is within a threshold difference of 50%. A duty cycle difference between the duty cycle of the state flag signal and a duty cycle of 50% may correspond to one of multiple duty cycle bins. The current track threshold may be adjusted based on the one of the multiple duty cycle bins corresponding to the duty cycle difference.

In some aspects, the current associated with the voltage regulator comprises an inductor current of the voltage regulator. In some aspects, the current associated with the voltage regulator comprises an output current of the voltage regulator. In some aspects, the current track threshold is adjusted to measure the first average of the current when the voltage regulator is operating in CCM.

In some aspects, the current assessment circuit may detect a set of operating cases associated with the current of the voltage regulator to be assessed, wherein the operating cases are associated with case-specific average currents for the voltage regulator, respectively. The current assessment circuit may generate an average current signal (e.g., also referred to herein as a “weight signal”) indicating the case-specific average currents for the voltage regulator, and identify a second average of the current across the set of operating cases based on the average current signal. In some aspects, the first average of the current may be assessed when the voltage regulator is operating in a CCM, and the second average of the current may be assessed when the voltage regulator is operating in a PSM. In some aspects, the current assessment circuit may select, via a multiplexer 814, between the first average of the current and the second average of the current based on an operating mode of the voltage regulator.

In some aspects, one or more functions of the voltage regulator may be controlled based on the first average of the current. In some aspects, one or more reports may be reported to an application or user based on the first average of the current.

FIG. 10 is a flow diagram illustrating example operations 1000 for current assessment, in accordance with certain aspects of the present disclosure. The operations 1000 may be performed for example, by a current assessment circuit such as the current assessment circuit 800 of FIG. 8.

At block 1002, the current assessment circuit may detect a set of operating cases associated with a current of a voltage regulator (e.g., SMPS) to be assessed. The operating cases may be associated with case-specific average currents for the voltage regulator, respectively.

At block 1004, the current assessment circuit may generate an average current signal (e.g., also referred to herein as a “weight signal”) indicating the case-specific average currents for the voltage regulator. At block 1006, the current assessment circuit may identify an average current across the set of operating cases based on the average current signal. In some aspects, the average current may be identified based on the case-specific average currents and durations of the operating cases.

In some aspects, the set of operating cases may include: a first operating case where the current of the voltage regulator is zero; a second operating case where the current increases from zero to a high-side current limit (HS-CL) for the voltage regulator; a third operating case where the current transitions between the HS-CL and a low-side current limit (LS-CL) for the voltage regulator; a fourth operating case where the current decreases from the LS-CL to less than the LS-CL; and a fifth operating case where the current increases from less than the LS-CL to the LS-CL.

In some aspects, identifying the average current comprises filtering the average current signal to identify the average current across the set of operating cases. In some aspects, the current assessment circuit detects an operating frequency for the voltage regulator and controls a bandwidth associated with the one or more filters based on the operating frequency. In some aspects, to detect the operating frequency, the current assessment circuit is configured to detect a frequency of control signaling for the voltage regulator.

In some aspects, one or more functions of the voltage regulator may be controlled based on the first average of the current. In some aspects, one or more reports may be reported to an application or user based on the first average of the current.

### EXAMPLE ASPECTS

Aspect 1: A current assessment circuit, comprising: a comparison circuit configured to compare a current associated with a voltage regulator with a current track threshold to yield a state flag signal; a duty cycle detection circuit configured to detect a duty cycle of the state flag signal; and a controller configured to adjust the current track threshold to assess a first average of the current based on the duty cycle of the state flag signal, wherein the current track threshold is adjusted by an amount based on the duty cycle.

Aspect 2: The current assessment circuit of Aspect 1, wherein the current track threshold is adjusted non-linearly based on the duty cycle.

Aspect 3: The current assessment circuit of Aspect 1 or 2, wherein the duty cycle detection circuit is configured to: generate a set of latch signals based on the state flag signal; and count a quantity of the latch signals that have a first logic value in an assessment cycle.

Aspect 4: The current assessment circuit of Aspect 3, wherein each of the set of latch signals is configured to transition from a second logic value low to the first logic value high based on the state flag signal.

Aspect 5: The current assessment circuit of Aspect 3 or 4, further comprising a pulse generator configured to generate a set of sequential pulses, wherein the duty cycle detection circuit is configured to generate each of the set of latch signals based on a respective one of the set of sequential pulses.

Aspect 6: The current assessment circuit of Aspect 5, wherein the pulse generator comprises a delay-locked loop (DLL).

Aspect 7: The current assessment circuit according to any of Aspects 1-6, wherein the controller is configured to adjust the current track threshold until the duty cycle is within a threshold difference of 50%.

Aspect 8: The current assessment circuit according to any of Aspects 1-7, wherein a duty cycle difference between the duty cycle of the state flag signal and a duty cycle of 50% corresponds to one of multiple duty cycle bins, wherein controller is configured to adjust the current track threshold based on the one of the multiple duty cycle bins corresponding to the duty cycle difference.

Aspect 9: The current assessment circuit of Aspect 8, wherein the controller is configured to apply a non-linear gain function to scale adjustments of the current track threshold in accordance with the duty cycle different associated with each of the multiple duty cycle bins.

Aspect 10: The current assessment circuit according to any of Aspects 1-9, wherein the current associated with the voltage regulator comprises an inductor current of the voltage regulator.

Aspect 11: The current assessment circuit according to any of Aspects 1-10, wherein the current associated with the voltage regulator comprises an output current of the voltage regulator.

Aspect 12: The current assessment circuit according to any of Aspects 1-11, wherein the controller is configured to adjust the current track threshold to measure the first average of the current when the voltage regulator is operating in a continuous conduction mode (CCM).

Aspect 13: The current assessment circuit according to any of Aspects 1-12, further comprising: an operating case detector configured to detect a set of operating cases associated with the current of the voltage regulator to be assessed, wherein the operating cases are associated with case-specific average currents for the voltage regulator, respectively; a weight circuit configured to generate an average current signal indicating the case-specific average currents for the voltage regulator; and an average detector configured to identify a second average of the current across the set of operating cases based on the average current signal.

Aspect 14: The current assessment circuit of Aspect 13, wherein: the first average of the current is configured to be assessed when the voltage regulator is operating in a continuous conduction mode (CCM); and the second average of the current is configured to be identified when the voltage regulator is operating in a pulse-skip mode (PSM).

Aspect 15: The current assessment circuit of Aspect 13 or 14, further comprising a multiplexer configured to select between the first average of the current and the second average of the current based on an operating mode of the voltage regulator.

Aspect 16: The current assessment circuit according to any of Aspects 1-15, wherein the voltage regulator comprises a switched-mode power supply (SMPS).

Aspect 17: A current assessment circuit, comprising: an operating case detector configured to detect a set of operating cases associated with a current of a voltage regulator to be assessed, wherein the operating cases are associated with case-specific average currents for the voltage regulator, respectively; a weight circuit configured to generate an average current signal indicating the case-specific average currents for the voltage regulator; and an average detector configured to identify an average current across the set of operating cases based on the average current signal.

Aspect 18: The current assessment circuit of Aspect 17, wherein the average detector is configured to identify the average current based on the case-specific average currents and durations of the operating cases.

Aspect 19: The current assessment circuit of Aspect 17 or 18, wherein the set of operating cases comprises: a first operating case where the current of the voltage regulator is zero; a second operating case where the current increases from zero to a high-side current limit (HS-CL) for the voltage regulator; a third operating case where the current transitions between the HS-CL and a low-side current limit (LS-CL) for the voltage regulator; a fourth operating case where the current decreases from the LS-CL to less than the LS-CL; and a fifth operating case where the current increases from less than the LS-CL to the LS-CL.

Aspect 20: The current assessment circuit according to any of Aspects 17-19, wherein the average detector comprises one or more filters configured to filter the average current signal to identify the average current across the set of operating cases.

Aspect 21: The current assessment circuit of Aspect 20, further comprising a frequency detector and controller configured to: detect an operating frequency for the voltage regulator; and control a bandwidth associated with the one or more filters based on the operating frequency.

Aspect 22: The current assessment circuit of Aspect 21, wherein, to detect the operating frequency, the frequency detector and controller is configured to detect a frequency of control signaling for the voltage regulator.

Aspect 23: The current assessment circuit according to any of Aspects 17-22, wherein the voltage regulator comprises a switched-mode power supply (SMPS).

Aspect 24: A method for current assessment, comprising: comparing a current associated with a voltage regulator with a current track threshold to yield a state flag signal; detecting a duty cycle of the state flag signal; and adjusting the current track threshold to assess a first average of the current based on the duty cycle of the state flag signal, wherein the current track threshold is adjusted by an amount based on the duty cycle.

Aspect 25: The method of Aspect 24, wherein the current track threshold is adjusted non-linearly based on the duty cycle.

Aspect 26: The method of Aspect 24 or 25, further comprising controlling one or more functions of the voltage regulator based on the first average of the current.

Aspect 27: The method according to any of Aspects 24-26, further comprising providing one or more reports to an application or user based on the first average of the current.

Aspect 28: The method according to any of Aspects 24-27, further comprising: generating a set of latch signals based on the state flag signal; and counting a quantity of the latch signals that have a first logic value in an assessment cycle.

Aspect 29: The method of Aspect 28, wherein each of the set of latch signals transitions from a second logic value low to the first logic value high based on the state flag signal.

Aspect 30: The method of Aspect 28 or 29, further comprising: generating a set of sequential pulses; and generating each of the set of latch signals based on a respective one of the set of sequential pulses.

Aspect 31: The method of Aspect 30, wherein the set of sequential pulses is generated via a delay-locked loop (DLL).

Aspect 32: The method according to any of Aspects 24-31, wherein the current track threshold is adjusted until the duty cycle is within a threshold difference of 50%.

Aspect 33: The method according to any of Aspects 24-32, wherein a duty cycle difference between the duty cycle of the state flag signal and a duty cycle of 50% corresponds to one of multiple duty cycle bins, wherein the current track threshold is adjusted based on the one of the multiple duty cycle bins corresponding to the duty cycle difference.

Aspect 34: The method according to any of Aspects 24-33, wherein the current associated with the voltage regulator comprises an inductor current of the voltage regulator.

Aspect 35: The method according to any of Aspects 24-34, wherein the current associated with the voltage regulator comprises an output current of the voltage regulator.

Aspect 36: The method according to any of Aspects 24-35, wherein the current track threshold is adjusted to measure the first average of the current when the voltage regulator is operating in a continuous conduction mode (CCM).

Aspect 37: The method according to any of Aspects 24-36, further comprising: detecting a set of operating cases associated with the current of the voltage regulator to be assessed, wherein the operating cases are associated with case-specific average currents for the voltage regulator, respectively; generating an average current signal indicating the case-specific average currents for the voltage regulator; and identifying a second average of the current across the set of operating cases based on the average current signal.

Aspect 38: The method of Aspect 37, wherein: the first average of the current is measured when the voltage regulator is operating in a continuous conduction mode (CCM); and the second average of the current is measured when the voltage regulator is operating in a pulse-skip mode (PSM).

Aspect 39: The method of Aspect 37 or 38, further comprising selecting between the first average of the current and the second average of the current based on an operating mode of the voltage regulator.

Aspect 40: A method for current assessment, comprising: detecting a set of operating cases associated with a current of a voltage regulator to be assessed, wherein the operating cases are associated with case-specific average currents for the voltage regulator, respectively; generating an average current signal indicating the case-specific average currents for the voltage regulator; and identifying an average current across the set of operating cases based on the average current signal.

Aspect 41: The method of Aspect 40, further comprising controlling one or more functions of the voltage regulator based on the average current.

Aspect 42: The method of Aspect 40 or 41, further comprising providing one or more reports to an application or user based on the average current.

Aspect 43: The method according to any of Aspects 40-42, wherein the average current is identified based on the case-specific average currents and durations of the operating cases.

Aspect 44: The method according to any of Aspects 40-43, wherein the set of operating cases comprises: a first operating case where the current of the voltage regulator is zero; a second operating case where the current increases from zero to a high-side current limit (HS-CL) for the voltage regulator; a third operating case where the current transitions between the HS-CL and a low-side current limit (LS-CL) for the voltage regulator; a fourth operating case where the current decreases from the LS-CL to less than the LS-CL; and a fifth operating case where the current increases from less than the LS-CL to the LS-CL.

Aspect 45: The method according to any of Aspects 40-44, wherein identifying the average current comprises filtering, via one or more filters, the average current signal to identify the average current across the set of operating cases.

Aspect 46: The method of Aspect 45, further comprising: detecting an operating frequency for the voltage regulator; and controlling a bandwidth associated with the one or more filters based on the operating frequency.

Aspect 47: The method of Aspect 46, wherein detecting the operating frequency comprises detecting a frequency of control signaling for the voltage regulator.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A current assessment circuit, comprising:
an operating case detector configured to detect a set of operating cases associated with a current of a voltage regulator to be assessed, wherein the operating cases are associated with case-specific average currents for the voltage regulator, respectively;
a weight circuit configured to generate an average current signal indicating the case-specific average currents for the voltage regulator; and
an average detector configured to identify an average current across the set of operating cases based on the average current signal.

2. The current assessment circuit of claim 1, wherein the average detector is configured to identify the average current based on the case-specific average currents and durations of the operating cases.

3. The current assessment circuit of claim 1, wherein the set of operating cases comprises:
a first operating case where the current of the voltage regulator is zero;
a second operating case where the current increases from zero to a high-side current limit (HS-CL) for the voltage regulator;
a third operating case where the current transitions between the HS-CL and a low-side current limit (LS-CL) for the voltage regulator;
a fourth operating case where the current decreases from the LS-CL to less than the LS-CL; and
a fifth operating case where the current increases from less than the LS-CL to the LS-CL.

4. The current assessment circuit of claim 1, wherein the average detector comprises one or more filters configured to filter the average current signal to identify the average current across the set of operating cases.

5. The current assessment circuit of claim 4, further comprising a frequency detector and controller configured to:
detect an operating frequency for the voltage regulator; and
control a bandwidth associated with the one or more filters based on the operating frequency.

6. The current assessment circuit of claim 5, wherein, to detect the operating frequency, the frequency detector and controller is configured to detect a frequency of control signaling for the voltage regulator.

7. The current assessment circuit of claim 1, wherein the voltage regulator comprises a switched-mode power supply (SMPS).

8. A method for current assessment, comprising:
detecting a set of operating cases associated with a current of a voltage regulator to be assessed, wherein the operating cases are associated with case-specific average currents for the voltage regulator, respectively;
generating an average current signal indicating the case-specific average currents for the voltage regulator; and
identifying an average current across the set of operating cases based on the average current signal.

9. The method of claim 8, further comprising controlling one or more functions of the voltage regulator based on the average current.

10. The method of claim 8, further comprising providing one or more reports to an application or user based on the average current.

11. The method of claim 8, wherein the average current is identified based on the case-specific average currents and durations of the operating cases.

12. The method of claim 8, wherein the set of operating cases comprises:
a first operating case where the current of the voltage regulator is zero;
a second operating case where the current increases from zero to a high-side current limit (HS-CL) for the voltage regulator;
a third operating case where the current transitions between the HS-CL and a low-side current limit (LS-CL) for the voltage regulator;
a fourth operating case where the current decreases from the LS-CL to less than the LS-CL; and
a fifth operating case where the current increases from less than the LS-CL to the LS-CL.

13. The method of claim 8, wherein identifying the average current comprises filtering, via one or more filters, the average current signal to identify the average current across the set of operating cases.

14. The method of claim 13, further comprising:
detecting an operating frequency for the voltage regulator; and
controlling a bandwidth associated with the one or more filters based on the operating frequency.

15. The method of claim 14, wherein detecting the operating frequency comprises detecting a frequency of control signaling for the voltage regulator.

16. An apparatus for voltage regulation, comprising:
a voltage regulator; and
a current assessment circuit comprising:
an operating case detector configured to detect a set of operating cases associated with a current of the voltage regulator to be assessed, wherein the operating cases are associated with case-specific average currents for the voltage regulator, respectively;
a weight circuit configured to generate an average current signal indicating the case-specific average currents for the voltage regulator; and
an average detector configured to identify an average current across the set of operating cases based on the average current signal.

17. The current assessment circuit of claim 16, wherein the average detector is configured to identify the average current based on the case-specific average currents and durations of the operating cases.

18. The current assessment circuit of claim 16, wherein the set of operating cases comprises:
a first operating case where the current of the voltage regulator is zero;
a second operating case where the current increases from zero to a high-side current limit (HS-CL) for the voltage regulator;
a third operating case where the current transitions between the HS-CL and a low-side current limit (LS-CL) for the voltage regulator;
a fourth operating case where the current decreases from the LS-CL to less than the LS-CL; and
a fifth operating case where the current increases from less than the LS-CL to the LS-CL.

19. The current assessment circuit of claim 16, wherein the average detector comprises one or more filters configured to filter the average current signal to identify the average current across the set of operating cases.

20. The current assessment circuit of claim 19, further comprising a frequency detector and controller configured to:
detect an operating frequency for the voltage regulator; and
control a bandwidth associated with the one or more filters based on the operating frequency.
